(19) United States
(12) Patent Application Publication
(10) Pub. No.: US 2024/0218213 A1
(43) Pub. Date: Jul. 4, 2024

(54) MASKING TAPE FOR FORMING ELECTROMAGNETIC WAVE SHIELD

(71) Applicant: NITTO DENKO CORPORATION, Osaka (JP)

(72) Inventor: Yuji OKAWA, Ibaraki-shi (JP)

(73) Assignee: NITTO DENKO CORPORATION, Osaka (JP)

(21) Appl. No.: 18/606,008

(22) Filed: Mar. 15, 2024

Related U.S. Application Data
(63) Continuation of application No. 17/321,901, filed on May 17, 2021.
Application No. 17/321,901 is a division of application No. 16/250,473, filed on Jan. 17, 2019, now abandoned.

(30) Foreign Application Priority Data
Jan. 19, 2018 (JP) 2018-006883

(51) Int. Cl. C09J 7/38; C08G 18/62; C08G 18/81; C09J 133/02; C09J 133/08; H01L 21/683; H01L 23/00; H01L 23/31

(52) U.S. Cl. CPC C09J 7/385; C08G 18/6225; C08G 18/8116; C09J 133/02; C09J 133/08; H01L 21/6836; H01L 24/00; C08G 2170/40; C09J 2203/326; C09J 2433/00; H01L 23/3128; H01L 2221/68377; Y10T 428/2809; Y10T 428/2891

(57) ABSTRACT

Provided is a masking tape to be used at the time of formation of an electromagnetic wave shield, which is excellent in followability to irregularities, and which is capable of being peeled off from an irregular surface without any adhesive residue. The masking tape for forming an electromagnetic wave shield includes a pressure-sensitive adhesive layer that is increased in modulus of elasticity through active energy ray irradiation to 20 times or more as high as that before the active energy ray irradiation, wherein the pressure-sensitive adhesive layer has a modulus of elasticity after the active energy ray irradiation of 500 MPa or less.

This is a continuation of application Ser. No. 17/321,901 filed May 17, 2021, which is a divisional of application Ser. No. 16/250,473 filed Jan. 17, 2019, which claims priority under 35 U.S.C. Section 119 to Japanese Patent Application No. 2018-006883 filed on Jan. 19, 2018, which are herein incorporated by references.

### BACKGROUND OF THE INVENTION

### 1. Field of the Invention

The present invention relates to a masking tape for forming an electromagnetic wave shield.

### 2. Description of the Related Art

An electromagnetic wave shield has hitherto been formed in an electronic component, and thus malfunction of the electronic component due to external electromagnetic waves, or leakage of electromagnetic waves generated from the electronic component is prevented. In recent years, from the viewpoint of downsizing of the electronic component, the electromagnetic wave shield (metal layer) has been directly formed in the electronic component by, for example, a sputtering method, a plating method, or a spraying method (for example, Japanese Patent Application Laid-open No. 2014-183180). At this time, a pressure-sensitive adhesive tape is attached to a surface on which the electromagnetic wave shield does not need to be formed, such as an electrode formation surface, so as to mask the surface.

In some cases, an electronic component having an irregular surface (e.g., an electronic component including a bump) is used as the electronic component. The pressure-sensitive adhesive tape used for masking of the irregular surface of such electronic component is required to satisfactorily follow irregularities to eliminate an unnecessary void space between the pressure-sensitive adhesive tape and an adherend surface, and to be capable of being peeled off therefrom without any adhesive residue after formation of the electromagnetic wave shield.

### SUMMARY OF THE INVENTION

An object of the present invention is to provide a masking tape to be used at the time of formation of an electromagnetic wave shield, which is excellent in followability to irregularities, and which is capable of being peeled off from an irregular surface without any adhesive residue.

According to one embodiment of the present invention, there is provided a masking tape for forming an electromagnetic wave shield, including a pressure-sensitive adhesive layer that is increased in modulus of elasticity through active energy ray irradiation to 20 times or more as high as that before the active energy ray irradiation, wherein the pressure-sensitive adhesive layer has a modulus of elasticity after the active energy ray irradiation of 500 MPa or less.

In one embodiment, the masking tape for forming an electromagnetic wave shield further includes a base material, wherein the pressure-sensitive adhesive layer is arranged on at least one side of the base material.

In one embodiment, the masking tape for forming an electromagnetic wave shield further includes an intermediate layer arranged on one side of the pressure-sensitive adhesive layer.

In one embodiment, the masking tape for forming an electromagnetic wave shield further includes an intermediate layer arranged between the pressure-sensitive adhesive layer and the base material.

In one embodiment, the pressure-sensitive adhesive layer has a modulus of elasticity (before the active energy ray irradiation) of from 0.07 MPa to 0.70 MPa.

In one embodiment, the intermediate layer has a modulus of elasticity of from 0.07 MPa to 0.30 MPa.

In one embodiment, the masking tape for forming an electromagnetic wave shield is subjected to a heating step of performing heating at a temperature of from 60° C. to 300° C.

In one embodiment, the masking tape for forming an electromagnetic wave shield is used for masking of a surface having a bump having a height of 50 μm or more.

According to the present invention, when the pressure-sensitive adhesive layer is formed so that the modulus of elasticity thereof can be changed through the active energy ray irradiation, and the modulus of elasticity is set to fall within a specific range, the masking tape to be used at the time of formation of an electromagnetic wave shield, which is excellent in followability to irregularities, and which is capable of being peeled off from an irregular surface without any adhesive residue, can be provided.

### BRIEF DESCRIPTION OF THE DRAWINGS

FIG. 1 is a schematic sectional view of a masking tape for forming an electromagnetic wave shield according to an embodiment of the present invention.

FIG. 2 is a schematic sectional view of a masking tape for forming an electromagnetic wave shield according to another embodiment of the present invention.

### DESCRIPTION OF THE EMBODIMENTS

### A. Summary of Masking Tape for Forming Electromagnetic Wave Shield

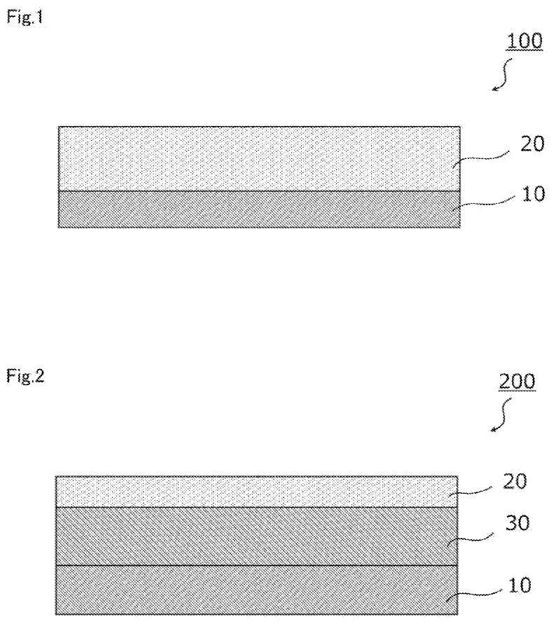

FIG. 1 is a schematic sectional view of a masking tape for forming an electromagnetic wave shield according to an embodiment of the present invention. A masking tape 100 for forming an electromagnetic wave shield according to this embodiment includes: a base material 10; and a pressure-sensitive adhesive layer 20 arranged on at least one side of the base material 10. While the illustration is omitted, for the purpose of protecting an adhesive surface, the masking tape of the present invention may include a release liner on an outside of the pressure-sensitive adhesive layer until use. As used herein, the “masking tape for forming an electromagnetic wave shield” is hereinafter sometimes referred to simply as “masking tape”.

The modulus of elasticity of the pressure-sensitive adhesive layer of the masking tape of the present invention can be changed through active energy ray irradiation. More specifically, the modulus of elasticity of the pressure-sensitive adhesive layer is increased through the active energy ray irradiation to 20 times or more as high as that before the active energy ray irradiation. As an active energy ray, there are given, for example, a gamma ray, an ultraviolet ray, visible light, an infrared ray (heat ray), a radio wave, an alpha ray, a beta ray, an electron beam, a plasma flow, an ionizing ray, and a particle beam. In one embodiment, the active energy ray irradiation is performed by irradiation with ultraviolet rays at a cumulative light amount of from 500 mJ/cm² to 4,000 mJ/cm² (preferably from 800 mJ/cm² to 1,500 mJ/cm², more preferably from 1,000 mJ/cm² to 1,500 mJ/cm²) (with a high-pressure mercury lamp at a wavelength around 365 nm). When the temperature of the pressure-sensitive adhesive layer is increased to 100° C. or more through long-term irradiation, the active energy ray is preferably radiated a plurality of times in a divided manner. The masking tape including the pressure-sensitive adhesive layer as described above can be attached to an irregular surface (e.g., a bump formation surface of a package) with satisfactory followability because the masking tape has appropriate flexibility when attached thereto. In addition, the masking tape can eliminate an unnecessary void space between an adherend surface and the masking tape. When a bump formation surface of a package is masked with such masking tape, formation of an unnecessary metal layer on the bump formation surface can be prevented at the time of forming an electromagnetic wave shield in the package. Meanwhile, after the masking tape is attached, the modulus of elasticity of the masking tape (substantially, the pressure-sensitive adhesive layer) can be increased through the active energy ray irradiation. For example, even when a masking tape-equipped package is subjected to a heating step (e.g., from 60° ° C. to 270° ° C., preferably from 60° ° C. to 200° C.), through use of the masking tape of the present invention, unnecessary penetration of the pressure-sensitive adhesive layer into a void space formed owing to irregularities (e.g., a void space between a bump bottom part and a bump formation surface) can be prevented because the pressure-sensitive adhesive layer has a high modulus of elasticity. As a result, when the masking tape is peeled off, remaining of a component of the pressure-sensitive adhesive layer (a so-called adhesive residue) on the adherend surface can be prevented. As described above, one of the accomplishments of the present invention is that, as a masking tape to be used at the time of forming an electromagnetic wave shield, the masking tape including the pressure-sensitive adhesive layer capable of exhibiting a modulus of elasticity suitable for each step can be provided.

FIG. 2 is a schematic sectional view of a masking tape for forming an electromagnetic wave shield according to another embodiment of the present invention. A masking tape 200 for forming an electromagnetic wave shield according to this embodiment further includes an intermediate layer 30. The intermediate layer 30 is arranged on one side of the pressure-sensitive adhesive layer 20. As illustrated in FIG. 2, when the masking tape 200 for forming an electromagnetic wave shield includes the base material 10, the intermediate layer 30 is arranged between the pressure-sensitive adhesive layer 20 and the base material 10. In one embodiment, the modulus of elasticity of the intermediate layer is lower than the modulus of elasticity of the pressure-sensitive adhesive layer after the active energy ray irradiation. When the intermediate layer is formed, a masking tape that maintains appropriate flexibility in its entirety and can satisfactorily mask an irregular surface while preventing unnecessary penetration of the pressure-sensitive adhesive layer into a void space formed owing to irregularities (e.g., a void space between a bump bottom part and a bump formation surface) can be obtained.

The masking tape of the present invention has an initial adhesion at 23° ° C. of preferably 0.4 N/20 mm or more, more preferably 0.5 N/20 mm or more when attached to a stainless steel plate. When the masking tape of the present invention has an initial adhesion falling within the above-mentioned range, a masking tape suitable for an electronic component can be obtained. The upper limit of the initial adhesion at 23° C. of the masking tape when attached to the stainless steel plate is, for example, 35 N/20 mm. The adhesion is measured in conformity with JIS Z 0237:2000. Specifically, the adhesion is measured by: attaching the masking tape to a stainless steel plate (arithmetic average surface roughness Ra: 50±25 nm) by reciprocating a 2-kilogram roller once; leaving the masking tape at 23° C. for 30 minutes; and then peeling off the masking tape under the conditions of a peeling angle of 180° and a peeling speed (drawing speed) of 300 mm/min. As used herein, the “initial adhesion” means an adhesion before the active energy ray irradiation.

The masking tape of the present invention may be reduced in adhesion through the active energy ray irradiation, but preferably has a predetermined adhesion after the active energy ray irradiation. After the masking tape is attached to a stainless steel plate and irradiated with ultraviolet rays (at a cumulative light amount of from 500 mJ/cm² to 4,000 mJ/cm² (preferably from 800 mJ/cm² to 1,500 mJ/cm², more preferably from 1,000 mJ/cm² to 1,200 mJ/cm²), the masking tape has an adhesion at 23° C. of preferably from 0.07 N/20 mm to 0.5 N/20 mm, more preferably from 0.08 N/20 mm to 0.3 N/20 mm. When the masking tape has an adhesion falling within the above-mentioned range, a masking tape capable of satisfactorily masking the electronic component in a step of forming an electromagnetic wave shield in the electronic component (e.g., a sputtering step, a plating step, or a spraying step) can be obtained.

The masking tape has a thickness of preferably from 70 μm to 600 μm, more preferably from 80 μm to 500 μm, still more preferably from 100 μm to 500 μm.

### B. Pressure-Sensitive Adhesive Layer

As described above, the modulus of elasticity of the pressure-sensitive adhesive layer is increased through the active energy ray irradiation to 20 times or more as high as that before the active energy ray irradiation. The modulus of elasticity of the pressure-sensitive adhesive layer is increased through the active energy ray irradiation to preferably from 20 times to 6,000 times, more preferably from 50 times to 5,500 times, still more preferably from 100 times to 4,000 times as high as that before the active energy ray irradiation. When an increase rate of the modulus of elasticity of the pressure-sensitive adhesive layer falls within the above-mentioned range, the above-mentioned effects of the present invention become more remarkable. As used herein, the “pressure-sensitive adhesive layer” means the pressure-sensitive adhesive layer before the active energy ray irradiation unless otherwise stated.

The modulus of elasticity of the pressure-sensitive adhesive layer (before the active energy ray irradiation) is preferably from 0.07 MPa to 0.7 MPa, more preferably from 0.075 MPa to 0.6 MPa, still more preferably from 0.08 MPa to 0.5 MPa, particularly preferably 0.1 MPa or more and less than 0.5 MPa. When the modulus of elasticity of the pressure-sensitive adhesive layer (before the active energy ray irradiation) falls within the above-mentioned range, a masking tape capable of appropriately following irregularities of the adherend surface can be obtained. In addition, when the masking tape is wound, sticking between overlapping portions of the masking tape can be prevented. Protrusion of a pressure-sensitive adhesive can also be prevented by radiating an active energy ray to an end surface portion of the masking tape in a roll shape.

The modulus of elasticity of the pressure-sensitive adhesive layer after the active energy ray irradiation is 500 MPa or less. When the modulus of elasticity of the pressure-sensitive adhesive layer after the active energy ray irradiation falls within the above-mentioned range, the pressure-sensitive adhesive layer to be obtained is less liable to be broken even after the active energy ray irradiation, and an adhesive residue on the adherend surface can be prevented. When the adherend surface is an irregular surface, the pressure-sensitive adhesive layer protruding into irregularities tends to be broken to be liable to cause the adhesive residue, but the masking tape of the present invention is useful because the masking tape can prevent the adhesive residue generated as described above. The modulus of elasticity of the pressure-sensitive adhesive layer after the active energy ray irradiation is preferably from 10 MPa to 500 MPa, more preferably from 100 MPa to 470 MPa, still more preferably from 120 MPa to 400 MPa. When the modulus of elasticity of the pressure-sensitive adhesive layer after the active energy ray irradiation falls within the above-mentioned range, the above-mentioned effects of the present invention become more remarkable. In one embodiment, as described above, the active energy ray irradiation is performed by irradiation with ultraviolet rays at a cumulative light amount of from 500 mJ/cm² to 4,000 mJ/cm² (preferably from 800 mJ/cm² to 1,500 mJ/cm², more preferably from 1,000 mJ/cm² to 1,200 mJ/cm²) (with a high-pressure mercury lamp at a wavelength around 365 nm).

As used herein, the “modulus of elasticity” means a modulus of elasticity at room temperature (23° C.) by a nanoindentation method. The modulus of elasticity by a nanoindentation method may be measured under the following conditions.
(Measurement Apparatus and Measurement Conditions)
Apparatus: Tribo Indenter manufactured by Hysitron, Inc.
Used indenter: Berkovich (trigonal type)
Measurement method: single penetration measurement
Set penetration depth: 2,500 nm
Penetration speed: 2,000 nm/sec
Measurement atmosphere: air
Sample size: 1 cm×1 cm

The pressure-sensitive adhesive layer has a thickness of preferably from 3 μm to 500 μm, more preferably from 5 μm to 450 μm, still more preferably from 10 μm to 400 μm. When the pressure-sensitive adhesive layer has a thickness falling within the above-mentioned range, a masking tape capable of appropriately following the irregularities of the adherend surface can be obtained. In one embodiment in which the masking tape does not include the intermediate layer, the pressure-sensitive adhesive layer has a thickness of preferably from 70 μm to 500 μm, more preferably from 80 μm to 450 μm, still more preferably from 100 μm to 400 μm. In another embodiment in which the masking tape includes the intermediate layer, the pressure-sensitive adhesive layer has a thickness of preferably from 3 μm to 100 μm, more preferably from 5 μm to 80 μm, still more preferably from 10 μm to 50 μm. When the masking tape includes the intermediate layer, the flexibility of the masking tape can be ensured by the intermediate layer, and hence the thickness of the pressure-sensitive adhesive layer can be reduced.

In one embodiment, the pressure-sensitive adhesive layer is formed of an active energy ray-curable pressure-sensitive adhesive.

In one embodiment, an active energy ray-curable pressure-sensitive adhesive (A1) containing a base polymer serving as a base material and an active energy ray-reactive compound (monomer or oligomer) capable of binding to the base polymer is used as the active energy ray-curable pressure-sensitive adhesive. In another embodiment, an active energy ray-curable pressure-sensitive adhesive (A2) containing an active energy ray-reactive polymer as a base polymer is used. The base polymer preferably has a functional group capable of reacting with a photopolymerization initiator. Examples of the functional group include a hydroxyl group and a carboxyl group. In the present invention, the modulus of elasticity of the pressure-sensitive adhesive layer can be appropriately adjusted by, for example: the kind and molecular weight of the base polymer; the kind and amount of the active energy ray-reactive compound; the kind and molecular weight of the active energy ray-reactive polymer; and the kind and amount of an additive contained in the active energy ray-curable pressure-sensitive adhesive (e.g., a cross-linking agent).

Examples of the base polymer to be used in the pressure-sensitive adhesive (A1) include: rubber-based polymers, such as a natural rubber, a polyisobutylene rubber, a styrene-butadiene rubber, a styrene-isoprene-styrene block copolymer rubber, a regenerated rubber, a butyl rubber, a polyisobutylene rubber, and a nitrile rubber (NBR); a silicone-based polymer; and an acrylic polymer. Those polymers may be used alone or in combination thereof. Of those, an acrylic polymer is preferred. When the acrylic polymer is used, a pressure-sensitive adhesive layer having characteristics (e.g., an adhesion and a modulus of elasticity) suitable for a semiconductor process can be formed.

The acrylic polymer is typically an acrylic polymer (homopolymer or copolymer) formed of at least one kind of alkyl (meth)acrylate serving as a monomer component. Specific examples of the alkyl (meth)acrylate include (meth)acrylic acid C1-C20 alkyl esters, such as methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, pentyl (meth)acrylate, isopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate.

For the purpose of improving a cohesion, heat resistance, a cross-linking property, or the like, as required, the acrylic polymer may have a constituent unit corresponding to another monomer component copolymerizable with the (meth)acrylic acid alkyl ester. Examples of such monomer component include: carboxyl group-containing monomers, such as acrylic acid and methacrylic acid; acid anhydride monomers, such as maleic anhydride and itaconic anhydride; hydroxyl group-containing monomers, such as hydroxyethyl (meth)acrylate and hydroxypropyl (meth)acrylate; sulfonic acid group-containing monomers, such as styrenesulfonic acid and allylsulfonic acid; (N-substituted) amide-based monomers, such as (meth)acrylamide and N,N-dimethyl(meth)acrylamide; an aminoalkyl (meth)acrylate-based monomer, such as aminoethyl (meth)acrylate; an alkoxyalkyl (meth)acrylate-based monomer, such as methoxyethyl (meth)acrylate; maleimide-based monomers, such as N-cyclohexylmaleimide and N-isopropylmaleimide; itaconimide-based monomers, such as N-methylitaconimide and N-ethylitaconimide; a succinimide-based monomer; vinyl-based monomers, such as vinyl acetate, vinyl propionate, N-vinylpyrrolidone, and methylvinylpyrrolidone; cyanoacrylate monomers, such as acrylonitrile and methacrylonitrile; an epoxy group-containing acrylic monomer, such as glycidyl (meth)acrylate; glycol-based acrylic ester monomers, such as polyethylene glycol (meth)acrylate and polypropylene glycol (meth)acrylate; acrylic acid ester-based monomers each having a heterocyclic ring, a halogen atom, a silicon atom, or the like, such as tetrahydrofurfuryl (meth)acrylate, fluorine (meth)acrylate, and silicone (meth)acrylate; olefin-based monomers, such as isoprene, butadiene, and isobutylene; and a vinyl ether-based monomer, such as vinyl ether. Those monomer components may be used alone or in combination thereof. Of those, a carboxyl group-containing monomer (particularly preferably acrylic acid or methacrylic acid) or a hydroxyl group-containing monomer (particularly preferably hydroxyethyl (meth)acrylate) is more preferred. When a constituent unit derived from such monomer is introduced, the photopolymerization initiator and the acrylic polymer (base polymer) can bind to each other, and the effects of the present invention become more remarkable. The content ratio of a constituent unit derived from the carboxyl group-containing monomer is preferably from 0.5 part by weight to 20 parts by weight, more preferably from 1 part by weight to 10 parts by weight with respect to 100 parts by weight of the acrylic polymer. The content ratio of a constituent unit derived from the hydroxyl group-containing monomer is preferably from 0.5 part by weight to 20 parts by weight, more preferably from 1 part by weight to 15 parts by weight with respect to 100 parts by weight of the acrylic polymer.

An example of the active energy ray-reactive compound that may be used in the pressure-sensitive adhesive (A1) is a photoreactive monomer or oligomer having a functional group having a polymerizable carbon-carbon multiple bond, such as an acryloyl group, a methacryloyl group, a vinyl group, an allyl group, or an acetylene group. Specific examples of the photoreactive monomer include: esterified products of (meth)acrylic acid and polyhydric alcohols, such as trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, 1,4-butanediol di(meth)acrylate, 1,6-hexanediol di(meth)acrylate, and polyethylene glycol di(meth)acrylate; a polyfunctional urethane (meth)acrylate; an epoxy (meth)acrylate; and an oligoester (meth)acrylate. In addition, a monomer, such as methacryloyl isocyanate, 2-methacryloyloxyethyl isocyanate (2-isocyanatoethyl methacrylate), or m-isopropenyl-α,α-dimethylbenzyl isocyanate, may be used. Specific examples of the photoreactive oligomer include dimers to pentamers of the above-mentioned monomers.

In addition, a monomer, such as epoxidized butadiene, glycidyl methacrylate, acrylamide, or vinyl siloxane, or an oligomer formed of such monomer may be used as the active energy ray-reactive compound.

Further, a mixture of an organic salt, such as an onium salt, and a compound having a plurality of heterocyclic rings in a molecule thereof may be used as the active energy ray-reactive compound. In the mixture, the organic salt cleaves through active energy ray (e.g., ultraviolet ray or electron beam) irradiation to generate an ion, and the ion serving as an initiating species may cause a ring opening reaction of the heterocyclic rings to form a three-dimensional network structure. Examples of the organic salt include an iodonium salt, a phosphonium salt, an antimonium salt, a sulfonium salt, and a borate salt. Examples of each of the heterocyclic rings in the compound having a plurality of heterocyclic rings in a molecule thereof include an oxirane ring, an oxetane ring, an oxolane ring, a thiirane ring, and an aziridine ring.

The content ratio of the active energy ray-reactive compound in the pressure-sensitive adhesive (A1) is preferably from 0.1 part by weight to 500 parts by weight, more preferably from 1 part by weight to 300 parts by weight, still more preferably from 2 parts by weight to 200 parts by weight with respect to 100 parts by weight of the base polymer.

Examples of the active energy ray-reactive polymer (base polymer) in the pressure-sensitive adhesive (A2) include polymers each having a functional group having a carbon-carbon multiple bond, such as an acryloyl group, a methacryloyl group, a vinyl group, an allyl group, or an acetylene group. Specific examples of the active energy ray-reactive polymers each having a functional group include: a polymer formed of a polyfunctional (meth)acrylate; a photo-cationic polymerizable polymer; a cinnamoyl group-containing polymer, such as polyvinyl cinnamate; a diazotized amino novolac resin; and polyacrylamide.

The pressure-sensitive adhesive (A2) may further contain the active energy ray-reactive compound (monomer or oligomer).

The base polymer constituting the pressure-sensitive adhesive has a weight-average molecular weight of preferably from 300,000 to 2,000,000, more preferably from 500,000 to 1,500,000. The weight-average molecular weight may be measured by GPC (solvent:THF).

The base polymer constituting the pressure-sensitive adhesive has a glass transition temperature of preferably from −50° ° C. to 30° C., more preferably from −40° C. to 20° C. When the base polymer has a glass transition temperature falling within the above-mentioned range, a masking tape excellent in heat resistance and capable of being suitably used in the heating step can be obtained.

The active energy ray-curable pressure-sensitive adhesive may contain a photopolymerization initiator. Any appropriate photopolymerization initiator may be used as the photopolymerization initiator. Examples of the photopolymerization initiator include: products under the product names of “Irgacure 369”, “Irgacure 379 ex”, “Irgacure 819”, “Irgacure OXE2”, and “Irgacure 127” manufactured by BASF; products under the product names of “Esacure One” and “Esacure 1001M” manufactured by Lamberti; and products under the product names of “Adeka Optomer N-1414”, “Adeka Optomer N-1606”, and “Adeka Optomer N-1717” manufactured by Adeka Corporation. The content ratio of the photopolymerization initiator is preferably from 1 part by weight to 20 parts by weight, more preferably from 2 parts by weight to 10 parts by weight with respect to 100 parts by weight of the base polymer in the pressure-sensitive adhesive.

The pressure-sensitive adhesive layer preferably contains a cross-linking agent. Examples of the cross-linking agent include an isocyanate-based cross-linking agent, an epoxy-based cross-linking agent, an oxazoline-based cross-linking agent, an aziridine-based cross-linking agent, a melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, and an amine-based cross-linking agent.

The content ratio of the cross-linking agent is preferably from 0.5 part by weight to 10 parts by weight, more preferably from 1 part by weight to 8 parts by weight with respect to 100 parts by weight of the base polymer of the pressure-sensitive adhesive. When the content ratio of the cross-linking agent falls within the above-mentioned range, the pressure-sensitive adhesive layer to be formed can be appropriately adjusted in modulus of elasticity. Further, when the content ratio of the cross-linking agent (preferably the isocyanate-based cross-linking agent) is set to fall within the above-mentioned range in the case of using the pressure-sensitive adhesive containing the base polymer having a carbon-carbon double bond, a residual rate of the carbon-carbon double bond can be increased after heating. As a result, a pressure-sensitive adhesive layer capable of being satisfactorily cured even after heating can be obtained.

In one embodiment, the isocyanate-based cross-linking agent is preferably used. The isocyanate-based cross-linking agent is preferred because the cross-linking agent can react with various kinds of functional groups. Specific examples of the isocyanate-based cross-linking agent include: lower aliphatic polyisocyanates, such as butylene diisocyanate and hexamethylene diisocyanate; alicyclic isocyanates, such as cyclopentylene diisocyanate, cyclohexylene diisocyanate, and isophorone diisocyanate; aromatic isocyanates, such as 2,4-tolylene diisocyanate, 4,4′-diphenylmethane diisocyanate, and xylylene diisocyanate; and isocyanate adducts, such as a trimethylolpropane/tolylene diisocyanate trimer adduct (manufactured by Nippon Polyurethane Industry Co., Ltd., product name “Coronate L”), a trimethylolpropane/hexamethylene diisocyanate trimer adduct (manufactured by Nippon Polyurethane Industry Co., Ltd., product name “Coronate HL”), and an isocyanurate form of hexamethylene diisocyanate (manufactured by Nippon Polyurethane Industry Co., Ltd., product name “Coronate HX”). A cross-linking agent having 3 or more isocyanate groups is preferably used.

The active energy ray-curable pressure-sensitive adhesive may further contain any appropriate additive as required. Examples of the additive include an active energy ray polymerization accelerator, a radical scavenger, a tackifier, a plasticizer (e.g., a trimellitic acid ester-based plasticizer, or a pyromellitic acid ester-based plasticizer), a pigment, a dye, a filler, an anti-aging agent, a conductive material, an antistatic agent, an ultraviolet ray absorber, a light stabilizer, a release modifier, a softener, a surfactant, a flame retardant, and an antioxidant.

### C. Base Material

The base material may be formed of any appropriate resin. Examples of the resin include: polyolefins, such as low density polyethylene, linear polyethylene, medium density polyethylene, high density polyethylene, ultra low density polyethylene, random copolymerization polypropylene, block copolymerization polypropylene, homopolypropylene, polybutene, and polymethylpentene; an ethylene-vinyl acetate copolymer; an ionomer resin; an ethylene-(meth)acrylic acid copolymer; an ethylene-(meth)acrylic acid ester (random or alternating) copolymer; an ethylene-butene copolymer; an ethylene-hexene copolymer; polyurethane; a polyester, such as polyethylene naphthalate; polyimide; polyether ketone; polystyrene; polyvinyl chloride; polyvinylidene chloride; a fluororesin; a silicon resin; a cellulose-based resin; and a cross-linked body thereof.

The resin constituting the base material has a glass transition temperature of preferably from 60° C. to 500° C., more preferably from 100° ° C. to 500° C. When the resin has a glass transition temperature falling within the above-mentioned range, a masking tape excellent in heat resistance and capable of being suitably used in the heating step can be obtained. The “glass transition temperature” means a temperature at which a loss tangent (tan δ) determined by a DMA method (drawing method) under the conditions of a temperature increase rate of 5° C./min, a sample width of 5 mm, a distance between chucks of 20 mm, and a frequency of 10 Hz has a peak.

The base material has a thickness of preferably from 12 μm to 250 μm, more preferably from 25 μm to 200 μm, still more preferably from 50 μm to 150 μm.

The modulus of elasticity of the base material is preferably from 300 MPa to 6,000 MPa, more preferably from 400 MPa to 5,000 MPa. When the modulus of elasticity of the base material falls within the above-mentioned range, a masking tape capable of appropriately following the irregularities of the adherend surface can be obtained.

The surface of the base material may be subjected to any appropriate surface treatment in order to improve, for example, adhesiveness to an adjacent layer and a retention property. Examples of the surface treatment include: chemical or physical treatments, such as chromic acid treatment, ozone exposure, flame exposure, high voltage electric shock exposure, and ionizing radiation treatment; and coating treatment.

### D. Intermediate Layer

The modulus of elasticity of the intermediate layer is preferably lower than the modulus of elasticity of the pressure-sensitive adhesive layer after the active energy ray irradiation. In addition, a configuration in which the modulus of elasticity of the intermediate layer is changed through the active energy ray irradiation may be adopted, but the modulus of elasticity of the intermediate layer after the active energy ray irradiation is preferably lower than the modulus of elasticity of the pressure-sensitive adhesive layer after the active energy ray irradiation.

The modulus of elasticity of the intermediate layer (the modulus of elasticity before ultraviolet ray irradiation when the modulus of elasticity is changed through the active energy ray irradiation) is preferably from 0.07 MPa to 0.7 MPa, more preferably from 0.075 MPa to 0.6 MPa, still more preferably from 0.08 MPa to 0.5 MPa. When the modulus of elasticity of the intermediate layer falls within the above-mentioned range, a masking tape capable of appropriately following the irregularities of the adherend surface can be obtained.

When the modulus of elasticity of the intermediate layer is changed through the active energy ray irradiation, the modulus of elasticity of the intermediate layer after the active energy ray irradiation is preferably from 0.05 MPa to 25 MPa, more preferably from 0.08 MPa to 20 MPa, still more preferably from 0.1 MPa to 15 MPa. When the modulus of elasticity of the intermediate layer falls within the above-mentioned range, a masking tape capable of appropriately following the irregularities of the adherend surface can be obtained.

The intermediate layer has a thickness of preferably from 100 μm to 500 μm, more preferably from 200 μm to 400 μm. When the intermediate layer has a thickness falling within the above-mentioned range, a masking tape capable of appropriately following the irregularities of the adherend surface can be obtained.

When the masking tape includes the intermediate layer, a total thickness of the thickness of the intermediate layer and the thickness of the pressure-sensitive adhesive layer is preferably from 103 μm to 510 μm, more preferably from 120 μm to 450 μm, still more preferably from 160 μm to 400 μm. When the total thickness falls within the above-mentioned range, a masking tape capable of appropriately following the irregularities of the adherend surface can be obtained.

Any appropriate material may be used as a material for forming the intermediate layer. In one embodiment, as a material for forming the intermediate layer, each of the following compositions is used: a composition (B1) for forming the intermediate layer containing the base polymer (preferably the acrylic polymer) described in the section B; a composition (B2) for forming the intermediate layer containing the base polymer (preferably the acrylic polymer) described in the section B and the active energy ray-reactive compound (monomer or oligomer) described in the section B; and a composition (B3) for forming the intermediate layer containing the active energy ray-reactive polymer described in the section B. In one embodiment, when a composition curable through the active energy ray irradiation is used as the composition for forming the intermediate layer, the masking tape of the present invention is provided as a masking tape including the intermediate layer after curing. In other words, in this embodiment, the masking tape includes the intermediate layer after curing and the pressure-sensitive adhesive layer before curing.

The content ratio of the active energy ray-reactive compound in the composition (B2) for forming the intermediate layer is preferably from 0.01 part by weight to 50 parts by weight, more preferably from 0.03 part by weight to 40 parts by weight, still more preferably from 0.04 part by weight to 30 parts by weight with respect to 100 parts by weight of the base polymer.

The composition for forming the intermediate layer may contain a photopolymerization initiator. Any appropriate photopolymerization initiator may be used as the photopolymerization initiator. Examples of the photopolymerization initiator include: products under the product names of “Irgacure 369”, “Irgacure 379 ex”, “Irgacure 819”, “Irgacure OXE2”, and “Irgacure 127” manufactured by BASF; products under the product names of “Esacure One” and “Esacure 1001M” manufactured by Lamberti; and products under the product names of “Adeka Optomer N-1414”, “Adeka Optomer N-1606”, and “Adeka Optomer N-1717” manufactured by Adeka Corporation. The content ratio of the photopolymerization initiator is preferably from 0.5 part by weight to 20 parts by weight, more preferably from 2 parts by weight to 10 parts by weight with respect to 100 parts by weight of the base polymer in the composition for forming the intermediate layer.

The composition for forming the intermediate layer preferably contains a cross-linking agent. Examples of the cross-linking agent include an isocyanate-based cross-linking agent, an epoxy-based cross-linking agent, an oxazoline-based cross-linking agent, an aziridine-based cross-linking agent, a melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, and an amine-based cross-linking agent.

The content ratio of the cross-linking agent is preferably from 0.1 part by weight to 10 parts by weight, more preferably from 0.5 part by weight to 8 parts by weight with respect to 100 parts by weight of the base polymer of the composition for forming the intermediate layer.

In one embodiment, the isocyanate-based cross-linking agent is preferably used. Specific examples of the isocyanate-based cross-linking agent include the compounds described in the section B.

The composition for forming the intermediate layer may further contain any appropriate additive as required. Examples of the additive include an active energy ray polymerization accelerator, a radical scavenger, a tackifier, a plasticizer (e.g., a trimellitic acid ester-based plasticizer, or a pyromellitic acid ester-based plasticizer), a pigment, a dye, a filler, an anti-aging agent, a conductive material, an antistatic agent, an ultraviolet ray absorber, a light stabilizer, a release modifier, a softener, a surfactant, a flame retardant, and an antioxidant.

### E. Production Method for Masking Tape

The masking tape may be produced by any appropriate method. The masking tape may be obtained by, for example, applying the pressure-sensitive adhesive onto the base material. As an application method, various method, such as bar coater application, air knife application, gravure application, gravure reverse application, reverse roll application, lip application, die application, dipping application, offset printing, flexo printing, and screen printing, may be adopted. In addition, it is also appropriate to adopt, for example, a method involving separately forming the pressure-sensitive adhesive layer on a release liner, and then bonding the liner to the base material. In addition, when the masking tape includes the intermediate layer, the masking tape may be obtained by applying (and, as required, curing) the composition for forming the intermediate layer onto the base material to form the intermediate layer, and then applying the pressure-sensitive adhesive onto the intermediate layer.

### F. Applications of Masking Tape

In forming an electromagnetic wave shield in an electronic component having an irregular surface (e.g., an electronic component including a bump), the masking tape of the present invention can be suitably used for masking of the irregular surface (bump formation surface) on which the electromagnetic wave shield does not need to be formed. In addition, the masking tape of the present invention can be suitably used as a masking tape when the electronic component that has been masked is subjected to a heating step.

In one embodiment, the masking tape of the present invention is used for masking of a surface having a bump having a height of 50 μm or more (e.g., from 50 μm to 400 μm). In general, the surface has a plurality of bumps. An arrangement distance between the bumps is, for example, from 100 μm to 500 μm. In addition, in one embodiment, the bumps each have a circular shape in a planar view, and each have a diameter of from 100 μm to 300 μm. When the masking tape of the present invention is used, the surface having the bumps as described above can be satisfactorily masked, and besides, the masking tape of the present invention can be peeled off from the surface without any adhesive residue.

In one embodiment, the masking tape of the present invention is subjected to a heating step of performing heating at a temperature of from 60° C. to 270° C. (preferably from 60° C. to 200° C.). More specifically, the masking tape of the present invention is subjected to the heating step after the pressure-sensitive adhesive layer is increased in modulus of elasticity through the active energy ray irradiation. Even when the masking tape of the present invention is subjected to such step, unnecessary penetration of the pressure-sensitive adhesive layer into a void space formed owing to irregularities (e.g., a void space between a bump bottom part and a bump formation surface) can be prevented. As a result, when the masking tape of the present invention is used, an adhesive residue can be prevented in a step in which the masking tape needs to be peeled off.

### EXAMPLES

The present invention is specifically described below by way of Examples, but the present invention is not limited to these Examples. Testing and evaluating methods in Examples are as described below. In addition, in Examples, “part(s)” and “%” are by weight unless otherwise specified.

### (1) Modulus of Elasticity

A pressure-sensitive adhesive layer of a masking tape was cut into a 1-centimeter square, and was used as a measurement sample. The measurement sample was fixed to a predetermined support and measured for a modulus of elasticity with a nanoindenter apparatus.

The nanoindenter apparatus and measurement conditions are as described below.

### (Measurement Apparatus and Measurement Conditions)

Apparatus: Tribo Indenter manufactured by Hysitron, Inc.
Used indenter: Berkovich (trigonal type)
Measurement method: single penetration measurement
Set penetration depth: 2,500 nm
Penetration speed: 2,000 nm/sec
Measurement atmosphere: air at 23° C.
Sample size: 1 cm×1 cm

In addition, the pressure-sensitive adhesive layer was irradiated with ultraviolet rays at a cumulative light amount of 1,000 mJ/cm² with UM-810 manufactured by Nitto Seiki Co., Ltd., and was then measured for a modulus of elasticity by the above-mentioned method.

### (2) Evaluation of Lifting of Masking Tape

A masking tape was attached to a bump formation surface of a BGA semiconductor package, and its pressure-sensitive adhesive layer was irradiated with ultraviolet rays at a cumulative light amount of 1,000 mJ/cm² with UM-810 manufactured by Nitto Seiki Co., Ltd. After that, a layer formed of SUS 0.2 μm/Cu 5 μm/SUS 0.5 μm was formed on the package through sputtering with CCS-1300 manufactured by Shibaura Mechatronics Corporation. Next, the masking tape was peeled off, and the bump formation surface was observed with a microscope. The degree of lifting of the masking tape was evaluated by the following criteria on the basis of a metal penetration amount at the periphery of the package. The BGA semiconductor package to be used had a size of 10 mm×10 mm×0.9 mmt and a height and a diameter of BGA (bump) of 200 μm and 200 μm, respectively. In addition, the masking tape was attached thereto under an environment at 40° ° C. by reciprocating a 2-kilogram rubber roll once.
∘: The metal penetration amount at the periphery of the package is 50 μm or less.
x: The metal penetration amount at the periphery of the package is 100 μm or more.

### (3) Evaluation of Adhesive Residue of Masking Tape

In the same manner as in the item (2), a masking tape was attached to a BGA semiconductor package, and then its pressure-sensitive adhesive layer was irradiated with ultraviolet rays at a cumulative light amount of 1,000 mJ/cm² with UM-810 manufactured by Nitto Seiki Co., Ltd. After that, the masking tape was peeled off, and the presence or absence of a pressure-sensitive adhesive layer component remaining on a bump formation surface was observed with a SEM (at a magnification of 50 times).
∘: No adhesive residue is present.
Δ: An adhesive residue at a level of several tens of micrometers is present in such a small amount that the adhesive residue is considered not to cause a problem in electrical connection.
x: An adhesive residue of 100 μm or more is observed in a large amount.

### [Production Example 1] Preparation of Pressure-sensitive Adhesive A

88.8 Parts of 2-ethylhexyl acrylate (hereinafter referred to as “2EHA”), 11.2 parts of 2-hydroxyethyl acrylate (hereinafter referred to as “HEA”), 0.2 part of benzoyl peroxide, and 65 parts of toluene were loaded into a reaction vessel equipped with a cooling tube, a nitrogen inlet tube, a thermometer, and a stirring apparatus, and were subjected to polymerization treatment at 61° C. for 6 hours in a stream of nitrogen to yield an acrylic polymer A having a weight-average molecular weight of 850,000. A molar ratio between 2EHA and HEA was set to 100 mol:20 mol.

12 Parts (80 mol % with respect to HEA) of 2-methacryloyloxyethyl isocyanate (hereinafter referred to as “MOI”) was added to the acrylic polymer A, and the contents were subjected to addition reaction treatment at 50° C. for 48 hours in a stream of air to yield an acrylic polymer A′.

Next, 2.5 parts of a polyisocyanate compound (product name “Coronate L”, manufactured by Nippon Polyurethane Industry Co., Ltd.), 5 parts of a photopolymerization initiator (product name “Irgacure 127”, manufactured by BASF), 30 parts of a mixture of dipentaerythritol pentaacrylate and dipentaerythritol hexaacrylate (product name “KAYARAD DPHA”, manufactured by Nippon Kayaku Co., Ltd.), and 6 parts of polyurethane acrylate (product name “SHIKOH UV-3000B”, manufactured by The Nippon Synthetic Chemical Industry Co., Ltd.) were added to 100 parts of the acrylic polymer A′. Thus, a pressure-sensitive adhesive A was produced.

### [Production Example 2] Preparation of Pressure-Sensitive Adhesive B

A pressure-sensitive adhesive B was prepared in the same manner as in Production Example 1 except that the blending amounts of “KAYARAD DPHA” and “SHIKOH UV-3000B” were changed to 60 parts and 12 parts, respectively.

### [Production Example 3] Preparation of Pressure-Sensitive Adhesive C

A pressure-sensitive adhesive C was prepared in the same manner as in Production Example 1 except that the blending amount of “KAYARAD DPHA” was changed to 100 parts and “SHIKOH UV-3000B” was not blended.

### [Production Example 4] Preparation of Pressure-Sensitive Adhesive D

A pressure-sensitive adhesive D was prepared in the same manner as in Production Example 1 except that “KAYARAD DPHA” and “SHIKOH UV-3000B” were not blended.

### [Production Example 5] Preparation of Pressure-Sensitive Adhesive E

A pressure-sensitive adhesive E was prepared in the same manner as in Production Example 1 except that the blending amount of “KAYARAD DPHA” was changed to 130 parts and “SHIKOH UV-3000B” was not blended.

### [Production Example 6] Formation of Intermediate Layer

90 Parts of 2-ethylhexyl acrylate (2EHA), 10 parts of acrylic acid (AA), 0.05 part of a photopolymerization initiator (product name “Irgacure 184”, manufactured by BASF), and 0.05 part of a photopolymerization initiator (product name “Irgacure 651”, manufactured by BASF) were loaded into a four-necked flask. Then, the mixture was exposed to ultraviolet rays under a nitrogen atmosphere to be partially photopolymerized to yield a partially polymerized product (an acrylic polymer syrup) having a polymerization degree of about 8 mass %.

0.04 Part of a photopolymerization initiator (product name “Irgacure 651”, manufactured by BASF) and 0.04 part of dipentaerythritol hexaacrylate were added to 100 parts of the acrylic polymer syrup, and the contents were uniformly mixed to prepare a composition for forming an intermediate layer.

One surface of a polyester film (product name: MRF, manufactured by Mitsubishi Polyester Film Corporation) having a thickness of 38 μm was subjected to release treatment with silicone, and the above-mentioned acrylic pressure-sensitive adhesive composition was applied onto the release-treated surface so as to give a final thickness of 300 μm. Thus, an application layer was formed. Next, another polyester film (product name: MRE, manufactured by Mitsubishi Polyester Film Corporation) having a thickness of 38 μm and having a surface subjected to release treatment with silicone was laminated onto the surface of the applied acrylic pressure-sensitive adhesive composition so that the release-treated surface of the film was on an application layer side. With this, the application layer (pressure-sensitive adhesive layer) formed of the optical acrylic pressure-sensitive adhesive composition was shielded from oxygen. The laminate thus obtained was irradiated with ultraviolet rays at an irradiance of 200 mW/cm² (measured with UVR-T1 manufactured by TOPCON having the maximum sensitivity at around 350 nm) with a high-pressure mercury lamp (manufactured by Toshiba Lighting & Technology Corporation) until a light amount reached 3,000 mW/cm². Thus, an intermediate layer sandwiched between the polyester films was obtained.

### Example 1-1

The pressure-sensitive adhesive A was applied onto a surface of a PET base material (thickness: 100 μm) that had been subjected to silicone treatment, and the pressure-sensitive adhesive was cross-linked under heating at 120° ° C. for 2 minutes to form a pressure-sensitive adhesive layer having a thickness of 10 μm.

Next, the intermediate layer obtained in Production Example 6 was transferred onto the pressure-sensitive adhesive layer, and the resultant was then stored under an environment at 50° C. for 48 hours. Thus, a masking tape (base material (100 μm)/intermediate layer (300 μm)/pressure-sensitive adhesive layer (10 μm)) was obtained.

The obtained masking tape was subjected to the above-mentioned evaluations (2) and (3). The results are shown in Table 1.

### Example 2-1, Example 3-1, Comparative Example 1-1, and Comparative Example 2-1

Masking tapes were each obtained in the same manner as in Example 1-1 except that a pressure-sensitive adhesive shown in Table 1 was used instead of the pressure-sensitive adhesive A. The obtained masking tapes were each subjected to the above-mentioned evaluations (2) and (3). The results are shown in Table 1.

### Example 1-2

The pressure-sensitive adhesive A was applied onto a surface of a PET base material (thickness: 100 μm) that had been subjected to silicone treatment, and the pressure-sensitive adhesive was cross-linked under heating at 80° C. for 5 minutes to form a pressure-sensitive adhesive layer “a” having a thickness of 135 μm.

The pressure-sensitive adhesive A was separately applied onto a PET release liner, and was cross-linked under heating at 80° C. for 5 minutes to form a pressure-sensitive adhesive layer “b” having a thickness of 135 μm.

The pressure-sensitive adhesive layer “b” was transferred onto the pressure-sensitive adhesive layer “a”, and the resultant laminate was then stored at 50° C. for 48 hours. Thus, a masking tape having a pressure-sensitive adhesive layer having a thickness of 270 μm was obtained.

The obtained masking tape was subjected to the above-mentioned evaluations (2) and (3). The results are shown in Table 1.

### Example 2-2, Example 3-2, Comparative Example 1-2, and Comparative Example 2-2

Masking tapes were each obtained in the same manner as in Example 1-2 except that a pressure-sensitive adhesive shown in Table 1 was used instead of the pressure-sensitive adhesive A. The obtained masking tapes were each subjected to the above-mentioned evaluations (2) and (3). The results are shown in Table 1.

TABLE 1

| | | | | | Comparative | Comparative |
|---|---|---|---|---|---|---|
| | | Example 1-1 | Example 2-1 | Example 3-1 | Example 1-1 | Example 2-1 |
| Pressure-sensitive adhesive | | Pressure- | Pressure- | Pressure- | Pressure- | Pressure- |
| | | sensitive | sensitive | sensitive | sensitive | sensitive |
| | | adhesive A | adhesive B | adhesive C | adhesive D | adhesive E |
| Composition of | Acrylic polymer | 100 | 100 | 100 | 100 | 100 |
| pressure- | A′ (part (s)) | | | | | |
| sensitive | DPHA (part(s)) | 30 | 60 | 100 | 0 | 130 |
| adhesive | UV-3000B | 6 | 12 | 0 | 0 | 0 |
| | (part(s)) | | | | | |
| Modulus of elasticity of | | 0.21 | 0.12 | 0.09 | 0.7 | 0.07 |
| pressure-sensitive adhesive layer | | | | | | |
| before ultraviolet ray irradiation | | | | | | |
| (MPa) | | | | | | |
| Modulus of elasticity of | | 129.2 | 359 | 459.3 | 10 | 510 |
| pressure-sensitive adhesive layer | | | | | | |
| after ultraviolet ray irradiation | | | | | | |
| (MPa) | | | | | | |
| Ratio of modulus of elasticity | | 6.2 × 10² | 3 × 10³ | 5.1 × 10³ | 14 | 7.3 × 10³ |
| after UV/modulus of elasticity | | | | | | |
| before UV | | | | | | |
| Thickness of pressure-sensitive | | 10 | 10 | 10 | 10 | 10 |
| adhesive layer (μm) | | | | | | |
| Intermediate layer (thickness: 300 | | Present | Present | Present | Present | Present |
| μm) | | | | | | |
| Evaluation of lifting | | ∘ | ∘ | ∘ | x | ∘ |
| Adhesive residue | | ∘ | ∘ | Δ | ∘ | x |
| | | | | | Comparative | Comparative |
| | | Example 1-2 | Example 2-2 | Example 3-2 | Example 1-2 | Example 2-2 |
| Pressure-sensitive adhesive | | Pressure- | Pressure- | Pressure- | Pressure- | Pressure- |
| | | sensitive | sensitive | sensitive | sensitive | sensitive |
| | | adhesive A | adhesive B | adhesive C | adhesive D | adhesive E |
| Composition of | Acrylic polymer | 100 | 100 | 100 | 100 | 100 |
| pressure- | A′ (part (s)) | | | | | |
| sensitive | DPHA (part(s)) | 30 | 60 | 100 | 0 | 130 |
| adhesive | UV-3000B | 6 | 12 | 0 | 0 | 0 |
| | (part(s)) | | | | | |

| | | | | | |
|---|---|---|---|---|---|
| Modulus of elasticity of | 0.21 | 0.12 | 0.09 | 0.7 | 0.07 |
| pressure-sensitive adhesive layer | | | | | |
| before ultraviolet ray irradiation | | | | | |
| (MPa) | | | | | |
| Modulus of elasticity of | 129.2 | 359 | 459.3 | 10 | 510 |
| pressure-sensitive adhesive layer | | | | | |
| after ultraviolet ray irradiation | | | | | |
| (MPa) | | | | | |
| Ratio of modulus of elasticity | 6.2 × 10² | 3 × 10³ | 5.1 × 10³ | 14 | 7.3 × 10³ |
| after UV/modulus of elasticity | | | | | |
| before UV | | | | | |
| Thickness of pressure-sensitive | 270 | 270 | 270 | 270 | 270 |
| adhesive layer (μm) | | | | | |
| Intermediate layer (thickness: 300 | Absent | Absent | Absent | Absent | Absent |
| μm) | | | | | |
| Evaluation of lifting | ∘ | ∘ | ∘ | x | ∘ |
| Adhesive residue | ∘ | ∘ | ∘ | ∘ | x |

The masking tape of the present invention can be suitably used as a masking tape for a vacuum process (e.g., a vacuum process in semiconductor production).

What is claimed is:

1. A method of forming an electromagnetic wave shield, comprising:
preparing a masking tape;
applying the masking tape to a surface of an electronic component on which an electromagnetic wave shield is not to be formed; and
performing active energy ray irradiation of the masking tape applied to the surface of the electronic component,
wherein the masking tape comprises a base material;
a pressure-sensitive adhesive layer including an active energy ray-curable pressure-sensitive adhesive (A1) containing a base polymer, and an active energy ray-reactive monomer or oligomer capable of binding to the base polymer, or an active energy ray-curable pressure-sensitive adhesive (A2) containing an active energy ray-reactive polymer as a base polymer, and
an intermediate layer arranged on one side of the pressure-sensitive adhesive layer and arranged between the base material and the pressure-sensitive adhesive layer,
wherein a modulus of elasticity of the pressure-sensitive adhesive layer after active energy ray irradiation is at least 20 times or higher than a modulus of elasticity before the active energy ray irradiation,
wherein the pressure-sensitive adhesive layer has a modulus of elasticity before active energy ray irradiation of from 0.07 MPa to 0.70 MPa,
wherein the pressure-sensitive adhesive layer has a modulus of elasticity after the active energy ray irradiation of 500 MPa or less,
wherein the intermediate layer has a modulus of elasticity before active energy ray irradiation of from 0.07 MPa to 0.70 MPa,
wherein the modulus of elasticity of the intermediate layer is lower than the modulus of elasticity of the pressure-sensitive adhesive layer after the active energy ray irradiation, and
wherein the active energy ray irradiation is performed by irradiation with ultraviolet rays at a cumulative light amount of from 500 mJ/cm² to 4,000 mJ/cm².

2. The method of forming an electromagnetic wave shield according to claim 1, further comprising performing heating of the masking tape after active energy ray irradiation at a temperature of from 60° ° C. to 270° ° C.

3. The method of forming an electromagnetic wave shield according to claim 1, wherein the the surface of the electronic component includes a bump having a height of 50 μm or more.

4. The method of forming an electronic wave shield according to claim 3, wherein the bump has a circular shape in a planar view and a diameter of from 100 μm to 300 μm.

5. The method of forming an electromagnetic wave shield according to claim 1, further comprising forming the electromagnetic wave shield on the electronic component.

6. The method of forming an electronic wave shield according to claim 1, further comprising peeling the masking tape off the surface of the electronic component after forming the electronic wave shield.
